(19) United States
(12) Patent Application Publication
(10) Pub. No.: US 2010/0187582 A1
(43) Pub. Date: Jul. 29, 2010

(54) SOLID-STATE IMAGING DEVICE HAVING TRANSMISSION GATES WHICH PASS OVER PART OF PHOTO DIODES WHEN SEEN FROM THE THICKNESS DIRECTION OF THE SEMICONDUCTOR SUBSTRATE

(75) Inventors: Motonari Katsuno, Kyoto (JP); Ryohei Miyagawa, Kyoto (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/752,624

(22) Filed: Apr. 1, 2010

Related U.S. Application Data
(62) Division of application No. 11/806,715, filed on Jun. 4, 2007.

(30) Foreign Application Priority Data
Jun. 15, 2006 (JP) 2006-166462
Dec. 18, 2006 (JP) 2006-340556

(51) Int. Cl. H01L 31/113

(52) U.S. Cl. 257/292; 257/E31.085

(57) ABSTRACT

A solid-state imaging device having a plurality of image pixels arranged along a main surface of a semiconductor substrate, wherein each of the plurality of image pixels includes a photodiode that converts incident light into an electric charge and a transmission gate that is formed so as to have a crossing area that partially passes over the photodiode when seen from the thickness direction of the semiconductor substrate. The transmission gate of the solid-state imaging device is formed in a manner that (i) a first region including a laminated body of a silicon film and a silicide film, and (ii) a second region that includes the silicon film and does not include the silicide film, both arranged along a main surface of the semiconductor substrate, and the second region in the transmission gate is formed in at least one part of the crossing area.

### BACKGROUND OF THE INVENTION

(1) Field of the Invention

The present invention relates to a solid-state imaging device having transmission gates which pass over part of photo diodes when seen from the thickness direction of the semiconductor substrate, and especially relates to a relative arrangement of a photo diode and a transmission gate in an image pixel of a MOS-type solid-state imaging device.

(2) Description of the Related Art

In recent years, CCD-type solid-state imaging devices and MOS-type solid-state imaging devices have become prevalent as imaging devices for use in digital still cameras and digital movie cameras. A semiconductor substrate of the MOS-type solid-state imaging device includes an image region that has a plurality of image pixels, and a peripheral circuit region that reads out signals from image pixels located in the image region.

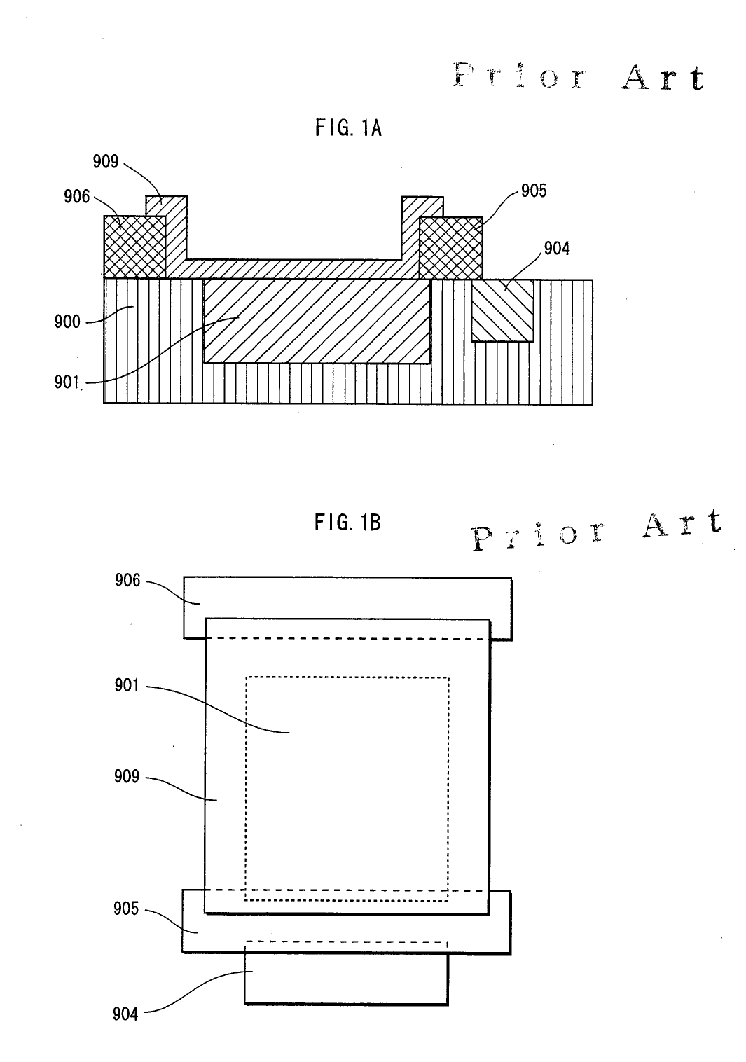

The MOS-type solid-state imaging devices are required to increase the device operating speed. One of the propositions made in the conventional art is the structure that includes silicide films which are formed so as to cover the whole or part of the tops s of transmission gates (see Japanese laid-open patent application No. 2001-345439). The following is a description of the solid-state imaging device that is proposed in the above-described document, with reference to FIG. 1A and FIG. 1B.

As shown in FIG. 1A, a solid-state imaging device that is proposed in the above-described document includes a photodiode 901 and a drain region which are embedded in a semiconductor substrate 900 from the main surface thereof, while being separated from each other by a predetermined distance. On the main surface of the semiconductor substrate 900, a transmission transistor gate 905 is formed so as to extend in a manner that overlaps the part of the photodiode 901 and a drain region 904. A reset transistor gate 906 (referred to as “reset gate” hereinafter) is formed on the opposite side of the transmission transistor gate 905 (referred to as “transmission gate” hereinafter) having the photodiode 901 therebetween.

Furthermore, in the above-described solid-state imaging device, a silicide film 909 is formed so as to cover the gates 905 and 906. As shown in FIG. 1B, when the solid-state imaging device of the conventional technology is seen in a planar view from above, the silicide film 909 is formed so as to cover the photodiode 901, and to partially cover the gates 905 and 906. The above-described document (Japanese laid-open patent application No. 2001-345439) provides various examples of modifications about the relationship between the gates 905, 906 and the silicide film 909 in addition to the structure shown in FIG. 1A and FIG. 1B.

For example, the descriptions include (i) a structure in which the silicide film 909 partially covers one of the gates 905 and 906, (ii) a structure in which the silicide film 909 covers both gates 905 and 906, and (iii) a structure in which the silicide film 909 partially covers one of the gates 905 and 906 while covering the remaining gate in a manner that passes over the top thereof.

Furthermore, the above-described document (Japanese laid-open patent application No. 2001-345439) provides (i) a structure in which the silicide film 909 partially covers the photodiode 901, and (ii) a structure in which the silicide film 909 completely covers the drain region 904.

Meanwhile, a solid-state imaging device is required to secure a certain gate length of a transmission gate in order to prevent the electron transmission (leak) that occurs when the transmission gate is turned off. A solid-state imaging device is also required to be miniaturized. To satisfy both of the requirements, a layout to arrange a transmission gate in the oblique direction with respect to the arrangement direction of image pixels (direction along the main surface of a semiconductor substrate), namely, the oblique readout layout may be adopted.

However, as is the case with metallic films, the silicide film 909 which is formed so as to cover the top of the transmission gate 905 in order to increase the device operating speed, completely reflects or partially absorbs light. Therefore, from the perspective of maintaining high sensitivity characteristics of the device, it is not advantageous to adopt the structure in which the silicide film 909 is formed over the whole surface of the photodiode 901, as seen in the above-described document (Japanese laid-open patent application No. 2001-345439). Also, in the case of adopting the oblique readout layout, forming the silicide film 909 gives rise to a problem that the amount of light to reach the photodiode 901 decreases. That means, with the conventional technologies, it is impossible to balance out the increase of the device operating speed and the high sensitivity characteristics.

### SUMMARY OF THE INVENTION

The object of the present invention is therefore to provide a solid-state imaging device with high sensitivity characteristics, and with increased device operating speed with use of the silicide film.

In order to achieve the above-described object, the present invention provides a solid-state imaging device including a plurality of image pixels that are arranged along a main surface of a semiconductor substrate, the solid-state imaging device comprising: a photodiode that is included in each of the plurality of image pixels, and converts incident light into an electric charge; and a transmission gate that includes a first region having a laminated body of a silicon film and a silicide film, and a second region having a silicon film, not a silicide film, both being arranged along the main surface of the semiconductor substrate, part of the transmission gate passing over part of the photodiode when seen from a thickness direction of the semiconductor substrate, wherein the part of the transmission gate includes at least part of the second region.

In the solid-state imaging device of the present invention that adopts the above-described structure, the transmission gate in each image pixel includes the first region (the region that includes a laminated body of a silicon film and a silicide film) and the second region (the region that includes a silicon film but does not include a silicide film) in the direction along the main surface of the semiconductor substrate, and the second region in the transmission gate which does not include a silicide film is provided in at least part of the crossing area (the area that passes over the photodiode) or in the whole crossing area. Here, the silicide film has an advantage of having low electric resistance. On the other hand, the silicide film also has a disadvantage of blocking or absorbing part of incident light.

Therefore, in the case of covering the photodiode with a silicide film as seen in the technology proposed in the above-described document (Japanese laid-open patent application No. 2001-345439), there is the disadvantage of lowering the sensitivity characteristic as well as the advantage of lowering the resistance of the transmission gate.

Accordingly, by taking into consideration the advantage and the disadvantage of the above-described silicide film, the present invention adopts the structure in which at least part of the crossing area includes the second region that does not include a silicide film, so that the second region prevents the incident light entering the photodiode from being blocked or absorbed. Therefore, the solid-state imaging device of the present invention can obtain high sensitivity characteristics by including the second region provided in at least part of the crossing area, and also can lower the resistance of the transmission gate by setting the remaining area as the first region that includes a silicide film. As a result, the solid-state imaging device of the present invention makes it possible to increase the device operating speed by lowering the resistance of the transmission gate while suppressing the deterioration of the sensitivity characteristics.

The following variations can be adopted in the solid-state imaging device of the above-described present invention. In the solid-state imaging device of the present invention, it is possible to adopt the structure in which, in the thickness direction of the semiconductor substrate, an upper main surface of the silicon film in the second region is positioned closer to the semiconductor substrate than an upper main surface of the silicide film of the first region. Here, “upper main surface” means the surface that faces the incident light.

Also, in the solid-state imaging device of the present invention, it is possible to adopt the structure in which the photodiode is polygonal shaped in the thickness direction of the semiconductor substrate, and the transmission gate passes over at least one of peripheral sides of the photodiode in an oblique direction

Also, in the solid-state imaging device of the present invention, it is possible to adopt the structure in which the part of the transmission gate includes at least part of the first region, and above the photodiode, the second region passes over an area inside the at least one of peripheral sides of the photodiode, and the first region passes over the photodiode excluding the area inside the peripheral side.

Also, in the solid-state imaging device of the present invention, it is possible to adopt the structure in which the first region passes over at least the part of the photodiode continuously.

Also, in the solid-state imaging device of the present invention, it is possible to adopt the structure in which, above the photodiode, the second region is arranged closer to a center of the photodiode than the first region, in a direction along the main surface of the semiconductor substrate.

Also, in the solid-state imaging device of the present invention, it is possible to adopt the structure in which the photodiode is substantially rectangular shaped in the thickness direction of the semiconductor substrate.

Also, in the solid-state imaging device of the present invention, it is possible to adopt the structure in which the photodiode is formed in part of an area which is extended inwardly in the thickness direction of the semiconductor substrate from the main surface thereof, a device isolation area surrounds the photodiode of the semiconductor substrate, the peripheral sides of the photodiode demarcate a boundary between the photodiode and the device isolation area, and the transmission gate partially passes over the photodiode while crossing the at least one of peripheral sides of the photodiode with substantially a 45-degree angle with respect to the photodiode. It should be noted here that above-described “substantially a 45-degree angle” means 45 [°]±5[°].

Also, in the solid-state imaging device of the present invention, it is possible to adopt the structure in which electric charge from the photodiode is readout in an orthogonal direction with respect to the oblique direction.

Also, in the solid-state imaging device of the present invention, it is possible to adopt the structure in which the silicide film includes at least one material selected from cobalt silicide, nickel silicide and titanium silicide.

Also, in the solid-state imaging device of the present invention, it is possible to adopt the structure in which the plurality of image pixels each include an n-type transistor, and the first region in the transmission gate is arranged so as to cover at least part of areas among a drain region, a source region and a gate of the n-type transistor.

Also, in the solid-state imaging device of the present invention, it is possible to adopt the structure in which each of the plurality of image pixels has a detection capacity region that reads out the electric charge generated by a photoelectric conversion in the photodiode, and the first region in the transmission gate covers over an area that includes at least a contact region of the detection capacity region.

Also, in the solid-state imaging device of the present invention, it is possible to adopt a multi-pixel cell structure.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

### In the Drawings:

FIG. 1A is a schematic sectional view that shows a structure of the photodiode 901 and the peripheral parts thereof in an image pixel of the solid-state imaging device of the conventional technologies;

FIG. 1B is a schematic planar view that planarly shows the photodiode 901 and the peripheral parts thereof;

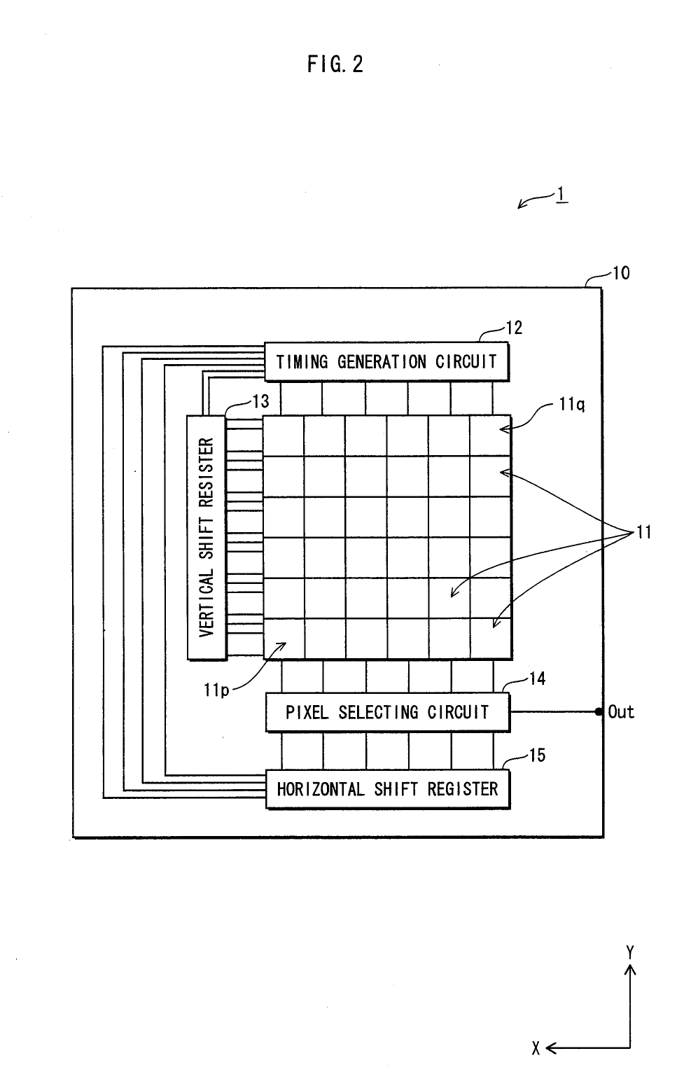

FIG. 2 is a schematic block view that shows a general structure of the solid-state imaging device 1 of the first embodiment;

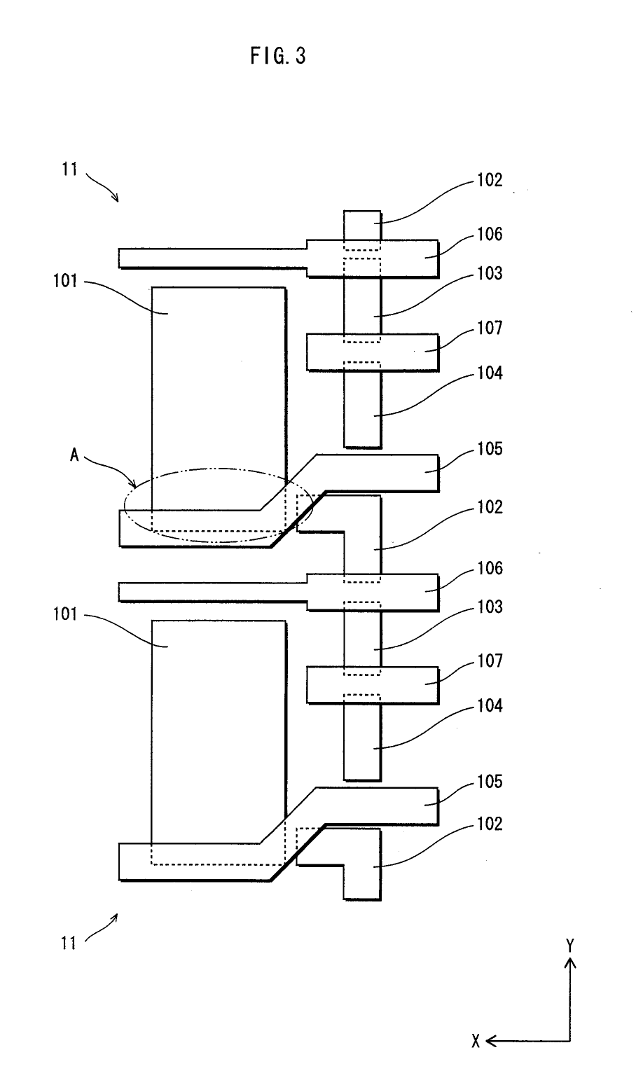

FIG. 3 is a schematic planar view that shows the main structure of part of the image pixels 11 in the solid-state imaging device 1;

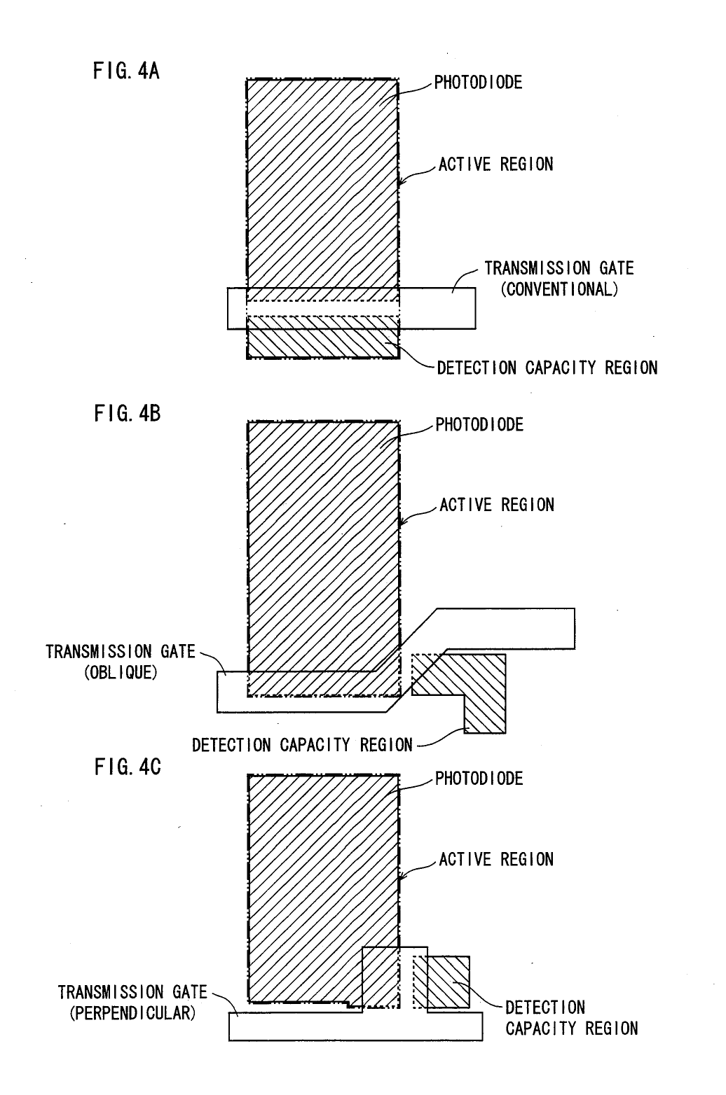

FIG. 4A is a diagram that shows a relationship between the arrangement of a transmission gate and area of a photodiode of the conventional structures;

FIG. 4B is a diagram that shows the arrangement of a transmission gate and area of a photodiode of the embodiment;

FIG. 4C is a diagram that shows a relationship between the arrangement of a transmission gate and area of a photodiode of variation;

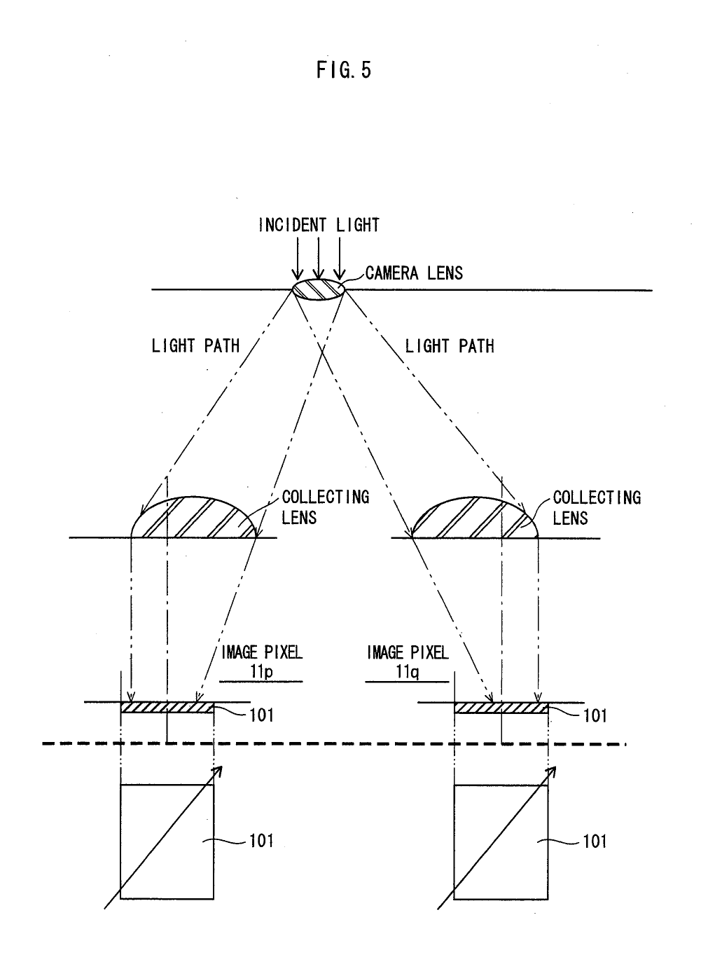

FIG. 5 is a schematic light path view that shows a light path of incident light of when a shape of a photodiode is symmetric;

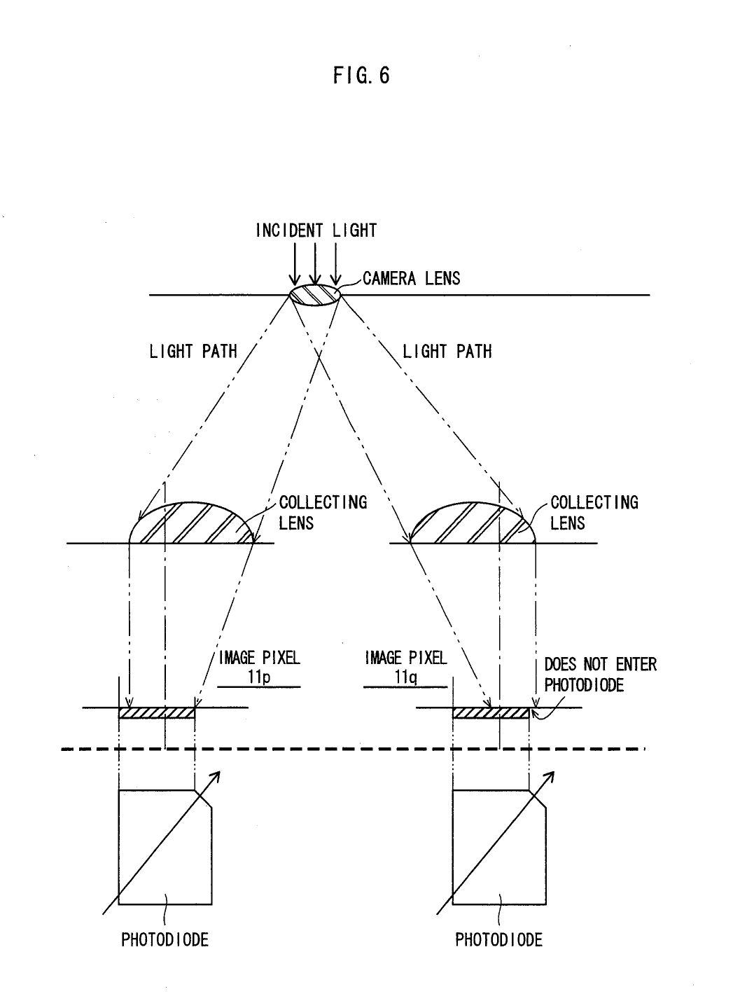

FIG. 6 is a schematic light path view that shows a light path of incident light of when a shape of a photodiode is asymmetric;

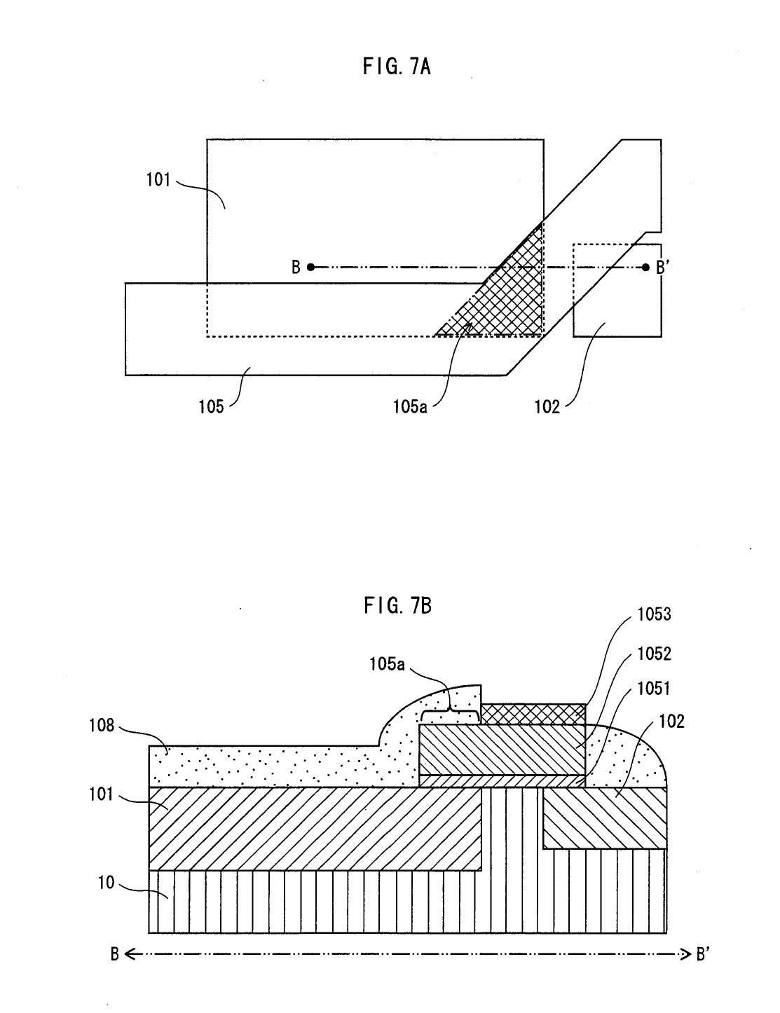

FIG. 7A is a schematic planar view that shows an arrangement of the photodiode 101 and the transmission gate 105 in the image pixel 11;

FIG. 7B is a schematic sectional view that shows a cross-sectional surface of B-B′ of the image pixel 11;

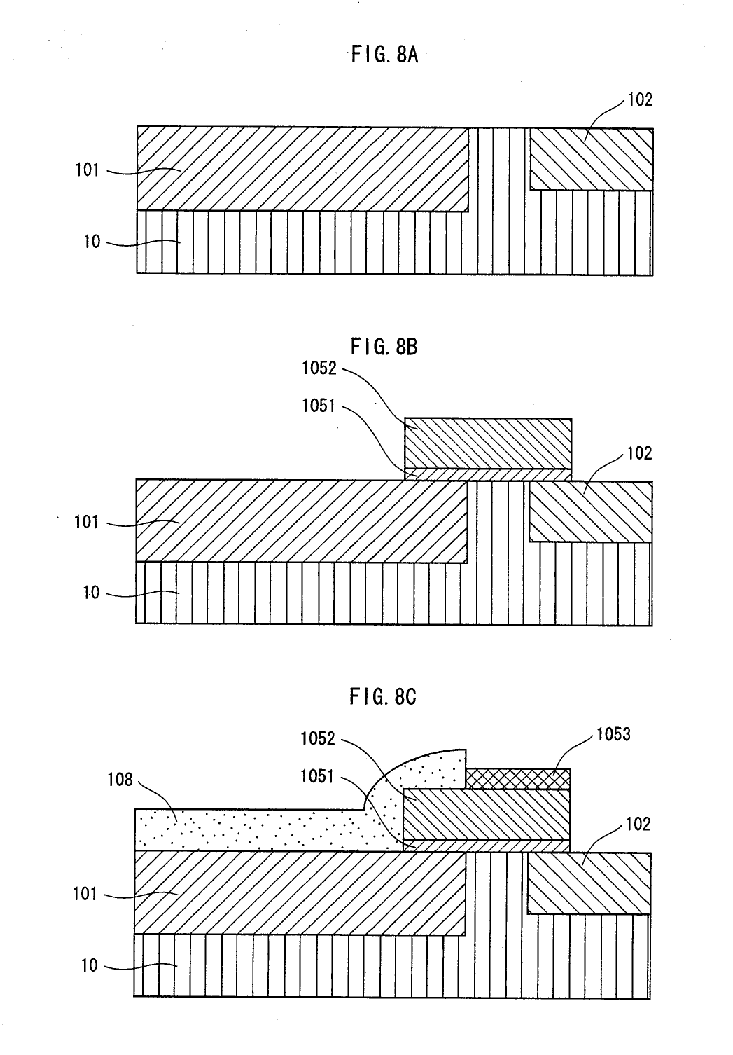

FIG. 8A is a schematic process chart that shows a process of forming the transmission gate 105 in the method of the solid-state imaging device 1;

FIG. 8B is a schematic process chart that shows a process of forming the transmission gate 105 in the method of the solid-state imaging device 1;

FIG. 8C is a schematic process chart that shows a process of forming the transmission gate 105 in the method of the solid-state imaging device 1;

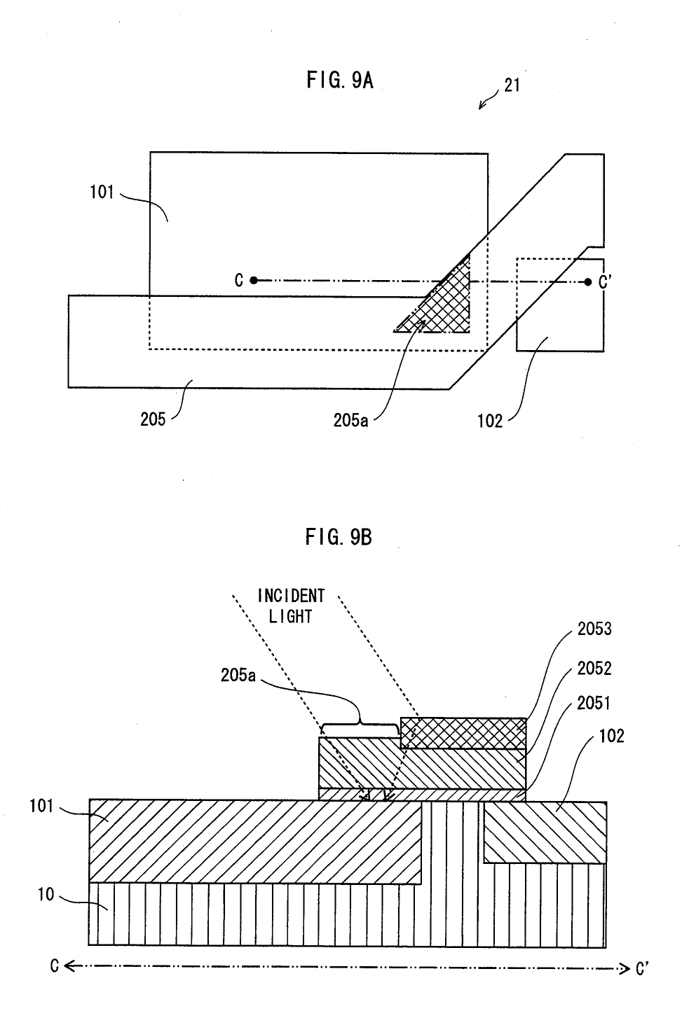

FIG. 9A is a schematic planar view that shows the arrangement of the photodiode 101 and the transmission gate 205 in the image pixel 21, among the components of the solid-state imaging device of the second embodiment;

FIG. 9B is a schematic sectional view that shows a cross-sectional surface of C-C′ of the image pixel 21;

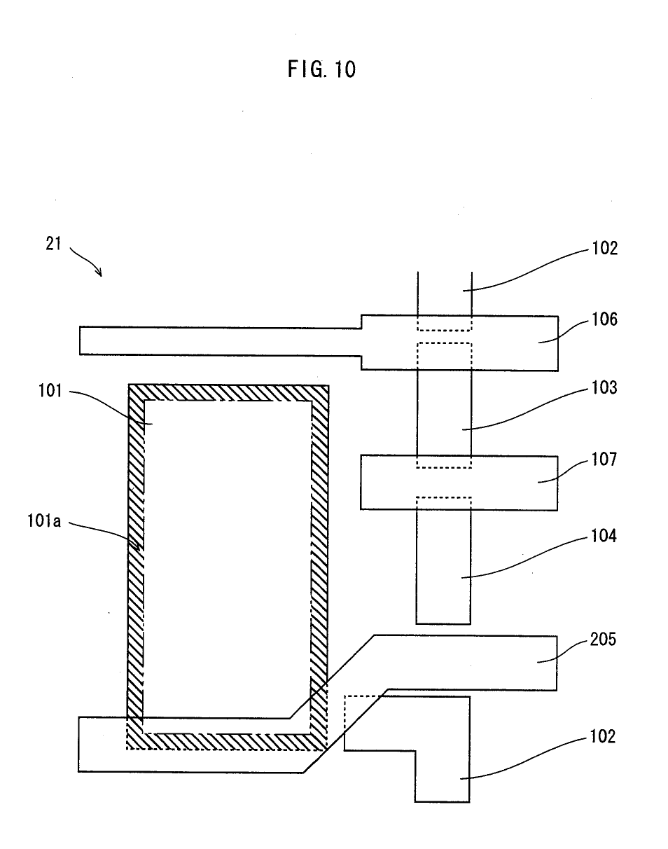

FIG. 10 is a schematic planar view that shows the accumulation of electrons in each part of a photodiode;

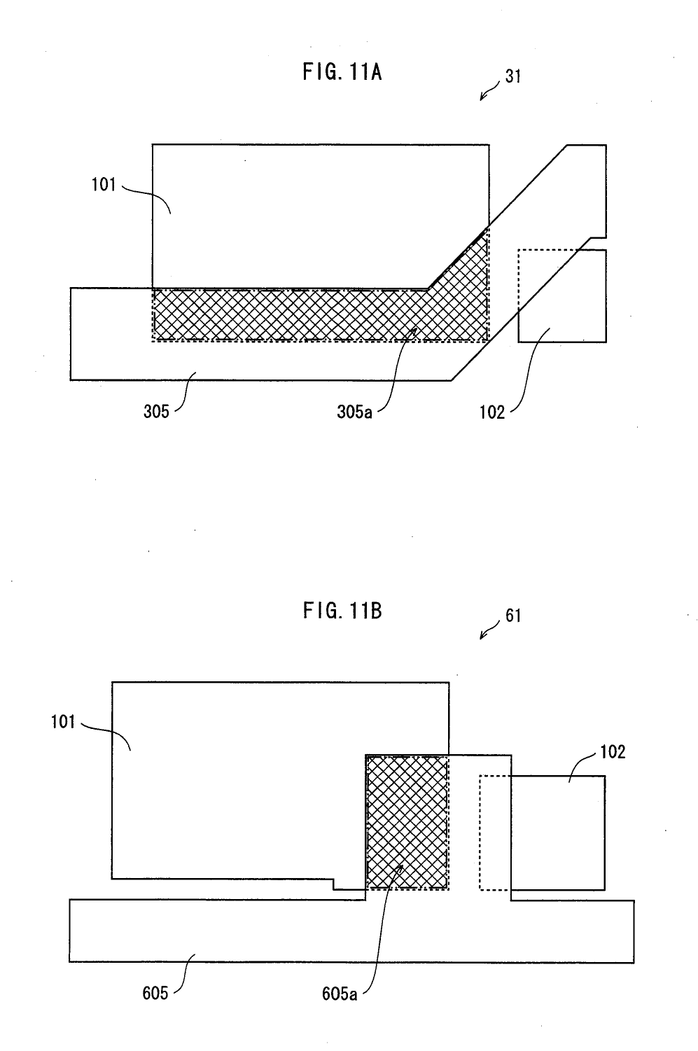

FIG. 11A is a schematic planar view that shows the arrangement of the photodiode 101 and the transmission gate 305 in the image pixel 31, among the components of the solid-state imaging device of the third embodiment;

FIG. 11B is a schematic planar view that shows the arrangement of the photodiode 101 and the transmission gate 605 in the image pixel 61 of the variation;

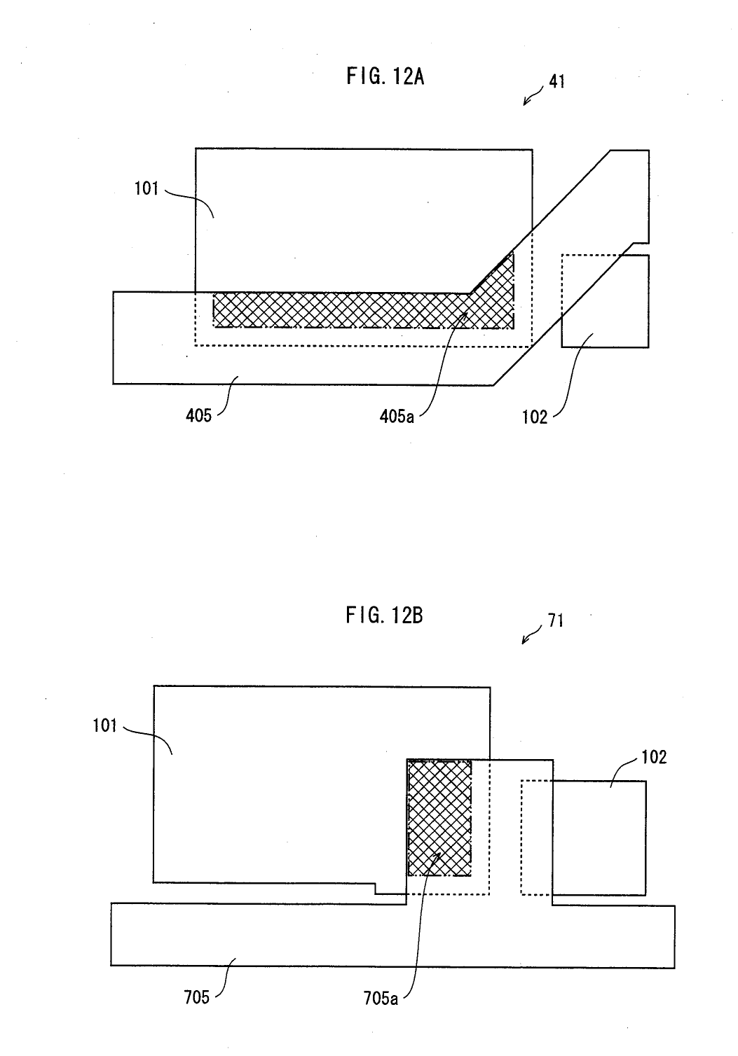

FIG. 12A is a schematic planar view that shows the arrangement of the photodiode 101 and the transmission gate 405 in the image pixel 41, among the components of the solid-state imaging device of the fourth embodiment;

FIG. 12B is a schematic planar view that shows the arrangement of the photodiode 101 and the transmission gate 705 in the image pixel 71 of the variation;

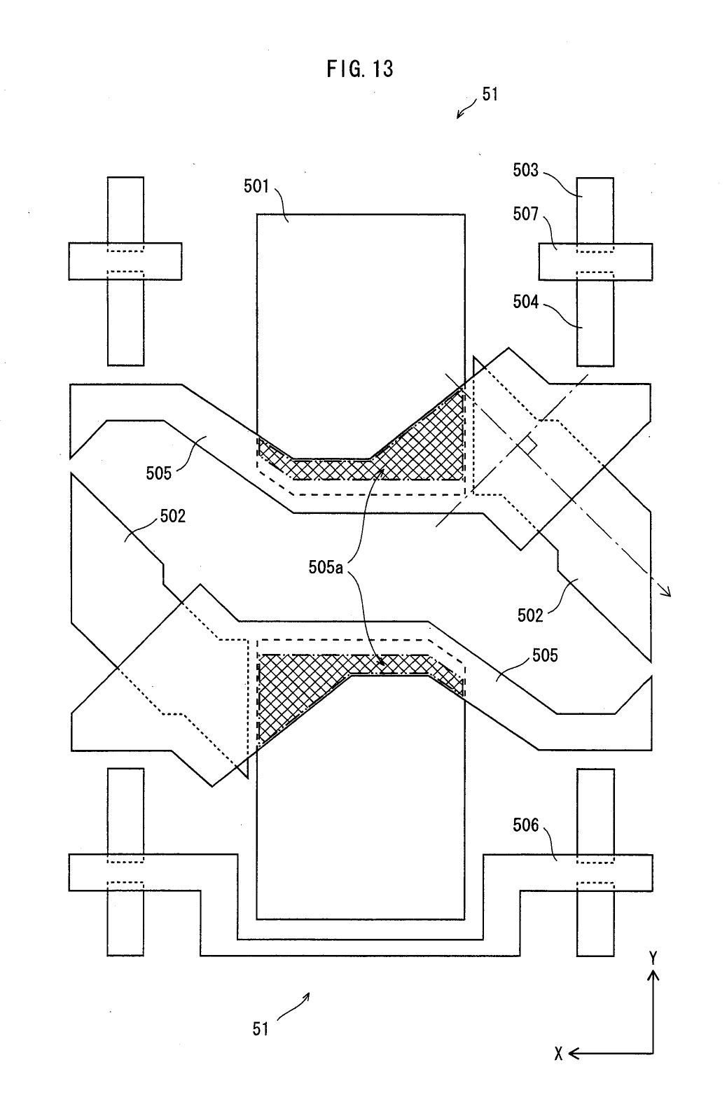

FIG. 13 is a schematic planar view that shows the main structure of the image pixel 51 in the solid-state imaging device of the fifth embodiment; and

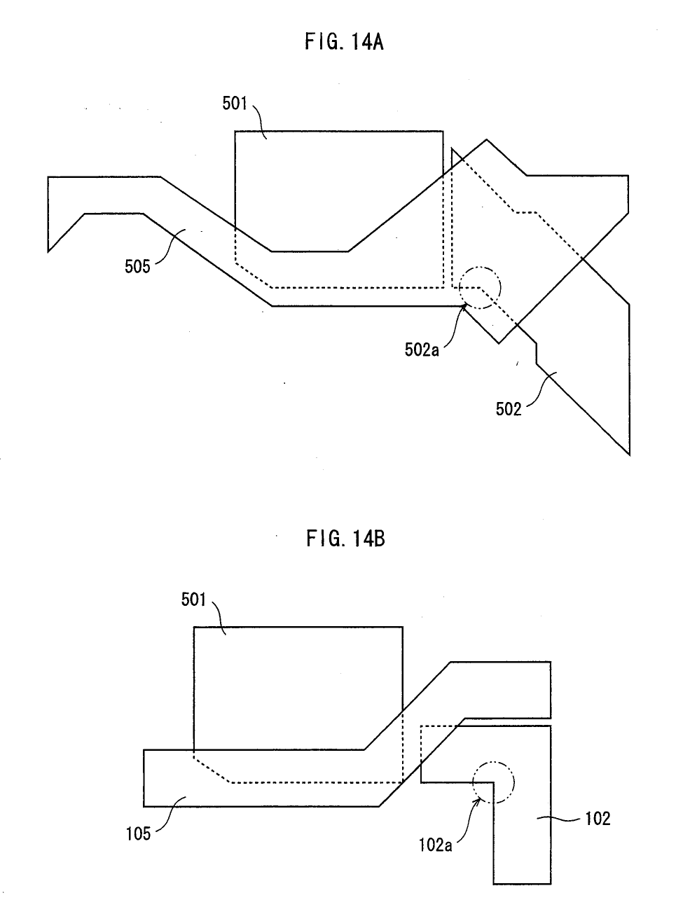

FIG. 14 shows a relationship between a shape of the floating diffusion region and the stress concentration.

### DESCRIPTION OF THE PREFERRED EMBODIMENT

The following describes the preferred embodiments of the present invention with reference to drawings. It should be noted that the embodiments used for the descriptions below are merely examples for the clear and detailed explanations of the structure of the present invention and the acts/effects achieved from the structure. Therefore the present invention shall not be limited to the embodiments that are described below except the essential characteristic parts.

### First Embodiment

1. General Structure of Solid-State Imaging Device 1

The following describes a general structure of a solid-state imaging device 1 of the first embodiment, with reference to FIG. 2, which is a schematic block view that shows a general structure of the solid-state imaging device 1 of the present embodiment. The solid-state imaging device 1 has a MOS-type structure, and is used as an imaging device in a digital still camera or a movie digital camera.

As shown in FIG. 2, the solid-state imaging device 1 of the present invention has a semiconductor substrate 10 as a base, and along one main surface thereof, (i) a plurality of image pixels 11 that are arranged in a matrix state and (ii) circuit units that are connected to each image pixel 11, are formed.

The circuit units of the solid-state imaging device 1 include a timing generation circuit 12, a vertical shift register 13, a pixel selecting circuit 14, and a horizontal shift register 15. The vertical shift register 13 and the horizontal shift register 15 are both formed by a dynamic circuit, and sequentially output a drive pulse (switching pulse) to image pixels 11 or the pixel selecting circuit 14 depending on a signal from the timing generation circuit 12.

The pixel selecting circuit 14 includes a switching device unit (not shown in figure) that corresponds by a unit of cell, and is sequentially turned on upon receiving the pulse from the horizontal shift register 15.

2. Structure of Image Pixel 11

In the structure of the solid-state imaging device 1 of the present embodiment, the following describes the main structure of the image pixel 11, with reference to FIG. 3.

As shown in FIG. 3, substantially rectangular shaped photodiodes 101 are formed on the semiconductor substrate 10 (not shown in FIG. 3). Each of the photodiodes 101 converts incident light into electric charge and stores the electric charge. Also, in the image pixel 11, a floating diffusion region (detection capacity region) 102 is formed adjacent to the photodiode 101. The floating diffusion region 102 is substantially L-shaped, and stores the transmitted electric charge that is generated in the photodiode 101.

As shown in FIG. 3, in the image pixel 11, a source region 103 is formed adjacent to the floating diffusion region 102 in Y axial direction, and a drain region 104 is formed adjacent to the source region 103 in Y axial direction.

In the image pixel 11, a transmission transistor gate 105 (referred to as “transmission gate” hereinafter) is formed to have a crossing area that partially passes over the photodiode 101 and the floating diffusion region 102, in the vertical direction with respect to the paper surface of FIG. 3 (in the thickness direction of the semiconductor substrate 10). A detailed description of the transmission gate 105 is provided below. Also, in the area between the floating diffusion region 102 and the source region 103, a reset transistor gate 106 (referred to as “reset gate” hereinafter) is formed in a manner that partially covers both regions 102 and 103. Between the source region 103 and the drain region 104, an amplifier transistor gate 107 (referred to as “amplifier gate” hereinafter) is formed in a manner that partially covers both regions 103 and 104.

It should be noted that device isolation regions are each formed in the area (i) between the image pixels 11 that are adjacent to each other, and (ii) between each of the functional regions 101-104 in the image pixel 11 (not shown in figure). The device isolation region is formed by one of STI structure (Shallow Trench Isolation) and LOCOS structure (Local Oxidation of Silicon). Here, in the image pixel 11, each of the impurity regions including the photodiode 101, the floating diffusion region 102, the source region 103, and the drain region 104 is arranged in the active regions excluding the device isolation regions.

Also, the transmission gates 105 are extended to connect to each other between the adjacent image pixels 11 so as to remain electrically connected. The transmission gates 105 may be connected to each other with use of (i) metallic lines arranged in the top layer and (ii) contact plugs that are used to connect the transmission gates 105 and the metallic lines.

The solid-state imaging device 1 of the present embodiment has a characteristic in which the transmission gate 105, which reads out the accumulated electric charge generated by a photoelectric conversion in the photodiode 101 to the floating diffusion region 102, is formed in the oblique direction with respect to the photodiode 101 and the floating diffusion region 102 in the horizontal and vertical directions. Specifically, as shown in FIG. 3, the electric charge that is accumulated in the photodiode 101 is read out to the floating diffusion region 102 that is located diagonally downward right.

As to the solid-state imaging device 1 of the present embodiment, the following are the reasons for forming the transmission gate 105 so as to have an oblique readout structure with respect to the photodiode 101 and the floating diffusion region 102.

The solid-state imaging device 1 is required to secure more than a certain gate length of the transmission gate 105 to prevent electron flow (leakage) between the photodiode 101 and the detection capacity region (floating diffusion region 102) while the transmission gate 105 is turned off. Therefore, in the solid-state imaging device 1 of the present embodiment, to achieve both requirements—(i) to suppress the leakage when the transmission gate is turned off and (ii) to miniaturize the device—, the transmission gate 105 is formed so as to have an oblique readout structure with respect to the photodiode 101 and the floating diffusion region 102.

Also, the solid-state imaging device 1 of the present embodiment has a structure in which part of the transmission gate 105 in each image pixel 11 is formed in the oblique direction with respect to the photodiode 101. Therefore, in the solid-state imaging device 1 of the present embodiment, the area to cover the photodiode 101 can be smaller than that of the conventional solid-state imaging device shown in FIG. 1A and FIG. 1B. The following provides a further explanation regarding to the above statement, with reference to FIG. 4A and FIG. 4B.

As shown in FIG. 4A, in the structure of the solid-state imaging device of the conventional technology, part of the active region (the region surrounded by the alternate long and two short dashes line shown in figure) is required to be allocated as a detection capacity region. Meanwhile, as shown in FIG. 4B, the solid-state imaging device 1 of the present embodiment is not required to allocate part of the active region (the region surrounded by the alternate long and two short dashes line shown in the figure) as the detection capacity region since the transmission gate 105 is arranged in the oblique direction. Therefore, in the solid-state imaging device 1 of the present embodiment, the whole active region can be used as the photodiode 101.

As a result, the solid-state imaging device 1 of the present embodiment makes it possible to enlarge the occupancy of the photodiode 101 to obtain the high sensitivity characteristics, compared to the solid-state imaging devices of the conventional technologies.

Also, in the solid-state imaging device 1 of the present embodiment, part of the transmission gate 105 in each image pixel 11 is set to be arranged in the oblique direction, which makes it possible to improve the photographic sensitivity compared to the solid-state imaging device of the conventional technologies shown in FIG. 1A and FIG. 1B. This results from the fact that the oblique arrangement of the part of the transmission gate 105 can decrease the absorption of the incident light in the polysilicon film of the area. It should be noted that the equivalent result can be achieved when an amorphous silicon film is adopted instead of the polysilicon film. The structure of the transmission gate 105 is described below.

Furthermore, in the solid-state imaging device 1 of the present embodiment, the shape of the photodiode 101 is formed so as to be substantially symmetric (formed in rectangular shape) in the horizontal direction and the vertical direction (X axial direction and Y axial direction). This is to prevent the distribution of the generated electric charge in the photodiode 101 from varying in the horizontal direction and the vertical direction (X axial direction and Y axial direction), and thereby preventing the deterioration in the shading characteristics of the solid-state imaging device 1.

It should be noted that the transmission gate in the shape shown in FIG. 4C may also be adopted. In such cases, in contrast to the transmission gate shown in FIG. 4B, the transmission gate is formed in the vertical direction with respect to the photodiode, rather than in the oblique direction. However, even when the transmission gate is formed so as to pass over one corner of the photodiode vertically, the same advantage of being able to use the whole active region as a photodiode can be obtained, as is the case with forming the transmission gate so as to pass over the photodiode obliquely.

Also, in the present embodiment, the shape of the photodiode is set to be rectangular. However, both substantially rectangular and polygonal shapes can be adopted so long as the shape is substantially symmetric in the horizontal and the vertical direction (X axial direction and Y axial direction).

The following describes the relationship between the shape of the photodiode 101 and the incident light, with reference to FIG. 5 and FIG. 6, which are the schematic light path views that show the light path of incident light, on the assumption of the two different shapes of the photodiode. The image pixels 11p and 11q in FIG. 5 and FIG. 6 show the two pixels that are positioned in the top right and the bottom left in the pixel array illustrated in FIG. 2.

As shown in FIG. 5, if the shape of the photodiode 101 in the image pixel 11 is set to be rectangular (symmetric shape) as seen in the solid-state imaging device 1 of the present embodiment, the same amount of light enters in both of the pixels 11p and 11q. Accordingly, in the solid-state imaging device of the present embodiment, the image pixels 11 across the whole area of the pixel array share the equivalent photosensitivity without causing the image characteristic deterioration, which makes it possible to obtain the high image characteristics.

Conversely, as shown in FIG. 6, if the shape of the photodiode is asymmetric, namely, if one corner of the rectangular shaped photodiode is cut off, although the incident light reaches the photodiode effectively in the image pixel 11p, part of the incident light does not reach the photodiode in the image pixel 11q. This results in having a difference in the amount of light among the image pixels in the pixel array, causing the defective image characteristics.

With the above description being provided, it is concluded that the solid-state imaging device 1 of the present embodiment in which the shape of the photodiode 101 in each image pixel 11 is symmetric can obtain the high image characteristics.

It should be noted that, as seen in the solid-state imaging device of the fifth embodiment that is described below, even when satisfying the other characteristics that are required for the solid-state imaging device (arranging the transmission gates symmetrically, securing the gate length of the transmission gates as long as possible, and the like), it is also preferable that the shape of each photodiode 11 is set to be symmetric in the horizontal direction and the vertical direction as much as possible.

Also, in the solid-state imaging device of the present embodiment, the photodiode 101 is formed so as to be arranged under the transmission gate 105, in order to (i) set the shape of the photodiode 101 to be substantially symmetric in the horizontal direction and the vertical direction (X axial direction and Y axial direction), and (ii) increase the saturation amount of electric charge that the photodiode 101 can manage.

3. Arrangement of Photodiode 101 and Transmission Gate 105, and Structure of Transmission Gate 105

The following describes the arrangement of the photodiode 101 and the transmission gate 105, and the structure of the transmission gate 105, with reference to FIG. 7A and FIG. 7B.

As shown in FIG. 7A, the transmission gate 105 in the image pixel 11 of the solid-state imaging device 1 is formed so as to have a crossing area in which part of the transmission gate 105 passes over the photodiode 101. The transmission gate 105 has an area 105a in the direction along the main surface of the semiconductor substrate 10.

As shown in FIG. 7B, the transmission gate 105 has a structure in which a gate oxide film 1051, a polysilicon film 1052, and a silicide film 1053 are laminated with each other in the order from the bottom to the top (from the side of the semiconductor substrate 10). Meanwhile, the area 105a, which is located in part of the crossing area in the transmission gate 105 (an area in which the transmission gate 105 passes over the photodiode 101), has a structure in which two layers including the gate oxide film 1051 and the polysilicon film 1052 are laminated with each other (the area 105a is referred to as “silicide unformed area” hereinafter). In other words, in the solid-state imaging device 1 of the present embodiment, the transmission gate 105 in the image pixel 11 does not include the silicide film 1053 in the part of the crossing area in which the transmission gate 105 passes over the photodiode 101 (silicide unformed area 105a).

It should be noted that, as shown in FIG. 7B, the silicon oxide film 108 completely covers the photodiode 101, and partially covers the polysilicon film 1052.

Here, the silicide film in the transmission gate 105 is formed of intermetallic compound material including metal and silicon, and has excellent electrical conductivity. Therefore, it is possible to lower the resistance by adding the silicide film 1053 to the transmission gate 105 in order to increase the device operating speed. However, the silicide film 1053 has a disadvantage of blocking or absorbing/reflecting part of incident light. Therefore, the solid-state imaging device of the present embodiment is formed in a manner that part of the area of the transmission gate that passes over the photodiode 101 is set to be the silicide unformed area 105a, and the remaining area in the transmission gate 105 includes the silicide film 1053.

Also, in the present embodiment, the polysilicon film 1052 is adopted as a component of the transmission gate 105. However, an amorphous silicon film can be adopted instead.

As described above, in the solid-state imaging device 1 of the present embodiment, the transmission gate 105 to perform an oblique readout is formed so as to pass over the photodiode 101, and the shape of the photodiode 101 is formed to be in a substantially symmetric shape (substantially rectangular shape) in the horizontal direction and the vertical direction (X axial direction and Y axial direction). Also, to increase the device operating speed by lowering the resistance of the transmission gate 105, a crossing area of the transmission gate 105 excluding the silicide unformed area 105a contains the silicide film 1053. In other words, the most specific characteristic of the solid-state imaging device 1 is the structure in which, while the silicide unformed area 105a of the transmission gate 105 on the part of the photodiode 101 does not include the silicide film 1053 to prevent the deterioration in the sensitivity characteristics, the remaining area in the transmission gate 105 includes the silicide film 1053 to increase the device operating speed.

Here, the reason the silicide film 1053 deteriorates the sensitivity characteristics is that the silicide film 1053 blocks or absorbs the light as described above. This effect increases as the size of the image pixel becomes smaller. For example, when the size of the image pixel 11 is in a range of 1 [μm] to 3 [μm] inclusive, the loss of the sensitivity characteristics by the silicide film is approximately 30[%] in general.

In the solid-state imaging device 1 of the present embodiment, when the film thickness of the polysilicon film 1052 that constitutes the transmission gate 105 is set to be, for example, in a range of 50 [nm] to 200 [nm] inclusive, the light transmittance of the polysilicon film 1052 disregarding the reflection is approximately in a range of 70[%] to 100[%] inclusive. However, in practice, the refraction occurs since the refractive index is different on the interface between the silicon oxide film 108 and the polysilicon film 1052, and the reflectance at this point is approximately 30[%] each. Therefore, when taking into consideration all the reflection, transmittance and absorption, the total light transmittance reaching the photodiode 101 is in a range of 49[%] to 70[%] inclusive.

Accordingly, the crossing area (silicide unformed area 105a) in the solid-state imaging device 1 of the present embodiment does not include the silicide film 1053 even though the transmission gate 105 is formed so as to pass over the photodiode 101. As a result, the light transmittance reaching the photodiode 101 remarkably improves compared to the solid-state imaging device described in the above-described document (Japanese laid-open patent application No. 2001-345439), achieving high sensitivity characteristics.

Also, in the solid-state imaging device 1 of the present embodiment, the transmission gate 105 excluding the silicide unformed area 105a has the silicide film 1053 in the structure, which makes it possible to lower the total resistance of the transmission gate 105, and to decrease the device operating speed. Furthermore, in the solid-state imaging device 1 of the present embodiment, the crossing area of the transmission gate 105 excluding the silicide unformed area 105a contains the silicide film 1053, so that the incident light does not easily enter the floating diffusion region 102 or the peripheral parts thereof by passing through the transmission gate 105. This effectively prevents the electrons from being generated by the photoelectric conversion in the semiconductor substrate 10 under the transmission gate 105. Therefore, the solid-state imaging device 1 of the present embodiment makes it possible to prevent the electrons from being generated by the undesired incident light, and to prevent the characteristic deterioration such as noise or image deterioration caused by the electrons.

4. Formation Method of Image Pixel 11

The following describes the formation method of the image pixel 11, which structurally has the most distinctive characteristic in the manufacturing method of the solid-state imaging device 1 of the present embodiment, with reference to FIG. 8A to FIG. 8C.

As shown in FIG. 8A, the photodiode 101 and the floating diffusion region 102 are embedded in the semiconductor substrate 10 from one of the main surface thereof to the thickness direction of the semiconductor substrate 10. The photodiode 101 and the floating diffusion region 102 are formed by implanting ion into the semiconductor substrate 10.

Next, a gate oxide preparation film and a polysilicon preparation film are laminated in sequence on the semiconductor substrate 10 in which the photodiode 101 and the floating diffusion region 102 are formed. The gate oxide preparation film and the polysilicon preparation film can be formed with use of a CVD method, a thermal oxidation method and the like. After the gate oxide preparation film and the polysilicon preparation film that are formed in the above-described method are patterned, unnecessary part of the films are removed by dry etching to form the gate oxide film 1051 and the polysilicon film 1052 shown in FIG. 8B.

Then, a silicon oxide film 108 is formed on the part excluding the area for the silicide film 1053. The silicon oxide film 108 is formed mainly with use of the CVD method. To form the silicide film 1053, metal to form the silicide film 1053 is deposited over the whole surface of the substrate, and a heat treatment is provided to produce reaction between the metal and the silicon. Here, the reaction does not occur on the preliminarily formed silicon oxide film 108. Therefore, by removing the metal on the silicon oxide film 108 after the silicide film 1053 is formed, the silicide film 1053 can be formed only in the appropriate place that excludes the silicide unformed area 105a (see FIG. 8C).

The metals that can be used to form the silicide film 1053 include cobalt, nickel and titanium. Also, it is preferable to form the silicide film 1053 over the whole or part of the drain/source/gate regions of the reset transistor and the amplifier transistor to increase the transistor operating speed.

In the present embodiment, it is preferable to further form the silicide film 1053 over part of the area that includes the contact region of the floating diffusion region. Here, “over part of the area” means that, when taking into consideration the variation during the manufacturing process, the area that secures the minimum margin required for forming the silicide film 1053 over the part of the area that includes the contact region of the floating diffusion region even though the contact deviation occurs. This is because increasing the device operating speed becomes difficult if the silicide film 1053 is not formed so as to cover the contact area of the floating diffusion region 102 since the contact resistance becomes high.

In other words, forming the silicide film 1053 on the semiconductor substrate 10 may cause substrate leakage due to the defect generation. The substrate leakage results in the electrons being detected even when the light does not enter the photodiode 101 and the electrons are not generated. This phenomenon is called “hot pixel”.

However, minimizing the area to form the silicide film on the above-described semiconductor substrate 10, as seen in the solid-state imaging device 1 of the present embodiment, makes it possible to minimize the leakage and suppress the image deterioration.

### Second Embodiment

The following describes the solid-state imaging device of the second embodiment, with reference to FIG. 9A and FIG. 9B. It should be noted that, in the solid-state imaging device of the present embodiment, the descriptions of the structures excluding the arrangement of the photodiode 101 and the transmission gate 205 are omitted since the descriptions are the same as the solid-state imaging device of the above-described first embodiment. In the structure of the solid-state imaging device of the present embodiment, FIG. 9A is the schematic planar view that shows the arrangement of the photodiode 101 and the transmission gate 205, and FIG. 9B is a schematic sectional view that shows the structure of the periphery of the photodiode 101 (a cross-sectional surface of C-C′ of FIG. 9A).

As shown in FIG. 9A, in the solid-state imaging device of the present embodiment, as is the case with the image pixel 11 of the solid-state imaging device of the above-described first embodiment, a transmission gate 205 is arranged so as to have a crossing area that partially passes over the photodiode 101 in each image pixel 21. It should be noted that the image pixel 21 also has the same functional parts as the image pixel 11 of the above-described solid-state imaging device 1 aside from the photodiode 101 and the transmission gate 205 (figures except the floating diffusion region are omitted).

It should be noted that, as is the case with the solid-state imaging device 1 of the above-described first embodiment, the image pixel 21 has a structure in which each impurity region including the photodiode 101, the floating diffusion region 102, the source region 103 and the drain region 104 is arranged in the active regions excluding the device isolation regions (figures omitted).

Also, the transmission gate 205 can remain electrically connected between the adjacent image pixels 21 by connecting the transmission gate 205 directly to other units as well as the photodiode 101 as an extended line. Also, the transmission gate 205 may be connected with use of metallic lines and the contact that are arranged in the upper part of the transmission gate 205.

It should be noted that, as is the case with the solid-state imaging device 1 of the above-described first embodiment 1, the transmission gate 205 is also formed to be the oblique readout with respect to the photodiode 101 and the floating diffusion region 102.

In the solid-state imaging device of the present embodiment, (i) the transmission gate 205 to perform the oblique readout is arranged above the photodiode 101, (ii) the shape of the photodiode 101 is formed to be substantially symmetric (rectangular shaped) in the vertical direction and the horizontal direction, and (iii) the silicide film 2053 is formed in the transmission gate 205 so as to realize the faster operating speed by lowering the resistance of the transmission gate 205. However, the hatching area 205a (silicide unformed area) shown in FIG. 9A does not include the silicide film 2053 (see FIG. 9B).

It should be noted that the solid-state imaging device of the present embodiment has a different structure in the crossing area in which the transmission gate 205 passes over the photodiode 101 in the oblique direction from the solid-state imaging device 1 of the above-described first embodiment. In the crossing area of the solid-state imaging device of the present embodiment, part of the transmission gate 205 that corresponds to the periphery of the photodiode 101 includes the silicide film 2053, and only the part that is oblique with respect to the photodiode 101 does not include the silicide film 2053. This is the main characteristic of the solid-state imaging device of the present embodiment.

Also, in the solid-state imaging device of the present embodiment, the area above the photodiode 101 that corresponds to the outer periphery thereof is covered with the silicide film 2053 to minimize the effect of the sensitivity deterioration (or shading). As shown in FIG. 10, a depletion layer (p-type layer) covers the periphery of the photodiode 101 (generally, n-type ion-implanted layer), which is the reason that a depletion layer covers the peripheral area 101a of the photodiode 101. Accordingly, the peripheral area 101a of the photodiode 101 has an extremely small number of accumulated electrons even though the peripheral area 101a receives incident light. Therefore, in the solid-state imaging device of the present embodiment, the silicide film 2053 covers the corresponding area above the peripheral area 101a of the photodiode 101, which is covered with the depletion layer. However, there is no major effect on the number of the accumulated electrons of the photodiode 101 caused by the silicide film 2053, and the characteristic deterioration in shading can be reduced.

As shown in FIG. 9B, in the solid-state imaging device of the present embodiment, as is the case with the above-described first embodiment, the transmission gate 205 is arranged so as to have (i) the area that includes the silicide film 2053 and (ii) the area that does not include the silicide film 2053.

Also, as shown in FIG. 9B, in the transmission gate 205 of the present embodiment, the surface of the polysilicon film 2052 in the silicide unformed area 205a is arranged in a higher (upper) position in the thickness direction of the semiconductor substrate 10 than a surface of the silicide film 2053 in other areas, namely, in the upstream direction of the incident light entering the device. Specifically, the surface of the polysilicon film 2052 in the silicide unformed area 205a is positioned to be lower, in the thickness direction of the semiconductor substrate 10, than the surface of the silicide film 2053 in the other areas by approximately in a range of 50 [nm] to 1 [μm].

The solid-state imaging device of the present embodiment that adopts the above-described structure includes the silicide film 2053 in the area corresponding to the periphery of the photodiode 101, which is in the crossing area of the transmission gate 205 that passes over the photodiode 101. This makes it possible to refract the incident light that enters the side wall of the silicide film 2053 in the corresponding area toward the photodiode 101. In the solid-state imaging device of the present embodiment, the above-described mechanism can prevent the incident light from entering the floating diffusion region 102 which is arranged under the transmission gate 205, and can realize high-quality image by suppressing the electron generation, which causes noise. The above is the reason that the area of the transmission gate 205 that passes over the area corresponding to the periphery of the photodiode 101 includes the silicide film 2053.

It should be noted that, in the solid-state imaging device of the present embodiment, it is preferable to secure the forming width of the silicide film 2053 in the transmission gate 205 in a range of 50 [nm] or above, from the perspective of lowering the electric resistance in the transmission gate 205. This is because the electric resistance drastically increases if the forming width of the silicide film is set to be narrower than 50 [nm]. In other words, silicide has a characteristic to aggregate and drastically increase the resistance if the forming width of the film is narrowed more than a predetermined line width.

In the present embodiment, the polysilicon film 2052 is adopted as a component of the transmission gate 205. However, as is the case with the above-described first embodiment, it is possible to adopt the amorphous silicon film instead.

### Third Embodiment

The following describes a solid-state imaging device of the third embodiment, with reference to FIG. 11A and FIG. 11B. FIG. 11A is a schematic view that shows the photodiode 101 and the transmission gate 305 in the image pixel 31, which are the most distinctive characteristics in the structure of the solid-state imaging device of the present embodiment. FIG. 11B is a schematic view that shows the photodiode 101 and the transmission gate 605 in the image pixel 61 as a variation.

As shown in FIG. 11A, as is the case with the solid-state imaging devices of the above-described first and second embodiments, the image pixel 31 of the solid-state imaging device of the present embodiment has a structure in which part of the transmission gate 305 passes over the photodiode 101, and the part thereof passes over one side of the periphery of the rectangular shaped photodiode 101 in the oblique direction. The difference between (i) the image pixel 31 of the present embodiment and (ii) each of the image pixels 11 and 21 of the above-described first and second embodiment is that, in the image pixel 31, the whole crossing area of the transmission gate 305 that passes over the photodiode 101 is set to be a silicide unformed area 305a. In other words, in the image pixels 11 and 21 of the above-described first and second embodiments, parts of the transmission gates 105 and 205 that passes over the photodiodes 101 are set to be the silicide unformed areas 105a and 205a respectively; however, in the image pixel 31 of the present embodiment, as shown in FIG. 11A, the whole area of the transmission gate that passes over the photodiode 101 is set to be the silicide unformed area 305a.

In the solid-state imaging device of the present embodiment that adopts such a structure, when compared to the solid-state imaging devices of the above-described embodiment 1 and 2, the silicide film does not exist over the photodiode; therefore, it is possible to further improve the sensitivity characteristics.

Also, in the solid-state imaging device of the present embodiment, as is the case with the above, it is preferable to secure the forming width of the silicide film in the transmission gate 305 in a range of 50 [nm] or more to prevent the increase of resistance of the transmission gate 305.

It should be noted that, also in the present embodiment, the transmission gate 305 includes the polysilicon film as a component. However, it is possible to use an amorphous silicon film instead.

Furthermore, as shown in FIG. 11B, in the image pixel 61 of the variation of the present embodiment, part of the transmission gate 605 passes over the photodiode 101, and the part thereof also partially passes over the periphery of the rectangular shaped photodiode 101 in the vertical direction and the horizontal direction. Even when such forms are adopted, the whole area of the transmission gate 605 that passes over the photodiode 101 is set to be the silicide unformed area 605a. In this way, in the solid-state imaging device that includes the image pixel 61 of the present variation, compared to the solid-state imaging devices of the above-described embodiments 1 and 2, the silicide film does not exist above the photodiode 101; therefore it is possible to further improve the sensitivity characteristics.

### Fourth Embodiment

The following describes the solid-state imaging device of the fourth embodiment, with reference to FIG. 12A and FIG. 12B. FIG. 12 A is a schematic view of the photodiode 101 and the transmission gate 405 in the image pixel 41, which are the most distinctive characteristics in the structure of the solid-state imaging device of the present embodiment. FIG. 12B is a schematic view that shows the photodiode 101 and the transmission gate 705 in the image pixel 71 as a variation.

As shown in FIG. 12A, in the image pixel 41 of the solid-state imaging device of the present embodiment, as is the case with the solid-state imaging devices of the above-described first, second and third embodiments, part of the transmission gate passes over the photodiode 101, and also passes over one of the peripheral sides of the rectangular shaped photodiode 101 in the oblique direction.

The difference between the image pixel 41 of the present embodiment and the image pixel 31 of the above-described third embodiment is that, in the image pixel 41, the silicide unformed area 405a is the area in which the transmission gate 405 passes over the photodiode 101 in the oblique direction, and also in the horizontal direction, excluding the area that corresponds to the periphery of the photodiode 101. In other words, in the image pixel 31 of the above-described third embodiment, the whole area of the transmission gate 305 that passes over the photodiode 101 is set to be the silicide unformed area 305a. However, in the image pixel 41 of the present embodiment, as shown in FIG. 12A, the area in the transmission gate 405 that corresponds to the periphery of the photodiode 101 includes the silicide film, but the remaining crossing area of the transmission gate 405 does not include the silicide film.

As described above, the solid-state imaging device of the present embodiment can lower the electric resistance and obtain high sensitivity characteristics compared to the above-described first and second embodiments since the area in the transmission gate 405 that corresponds to the periphery of the photodiode 101 includes the silicide film as the component, and the remaining crossing area of the transmission gate 405 (silicide unformed area 405a) does not include the silicide film as the component. Also, the solid-state imaging device of the present embodiment has a structure in which the transmission gate 405 includes a silicide film in the area that corresponds to the periphery of the photodiode 101, which prevents the incident light from entering the floating diffusion region 102 that is located under the transmission gate 405, and can realize the high-quality image by suppressing the electron generation that causes noise. In other words, the solid-state imaging device of the present embodiment has the advantages of both of the solid-state imaging devices of the above-described second and third embodiment.

Furthermore, in the solid-state imaging device of the present embodiment, the surface of the polysilicon film in the silicide unformed area 405a is arranged to be in a higher (upper) position in the thickness direction of the semiconductor substrate 10 than a surface of the silicide film in other areas, namely, on the upstream side of the incident light entering toward the device. Specifically, the surface of the polysilicon film in the silicide unformed area 405a is positioned to be substantially 50 [nm] to 1 [μm] lower than the surface of the silicide film in the other areas in the thickness direction of the semiconductor substrate 10.

The solid-state imaging device of the present embodiment that adopts the above-described structure can also reflect the incident light in the direction of the photodiode 101 when the incident light enters the side wall of the silicide film, thereby preventing the incident light from entering the bottom part of the transmission gate 407, and the floating diffusion region 102. As a result, the electron generation that causes noise can be suppressed and the high-quality image can be realized. Also, adopting the above-described structure can have the following two advantages.

(1) The first advantage is the ability to lower the resistance of the transmission gate 405 since the width of the silicide film can be set to be larger than that of the solid-state imaging device of the third embodiment shown in FIG. 11A. As a result, the solid-state imaging device of the present embodiment can achieve the further increase in speed than the solid-state imaging device of the above-described third embodiment.
(2) The second advantage is that the area above the periphery of the photodiode 101 is covered with the silicide film, thereby minimizing the sensitivity deterioration (or shading). This is, as described above, based on the fact that the number of accumulated electrons is extremely small even though the incident light enters the peripheral area 101a of the photodiode 101 since a depletion layer covers the peripheral area 101a (see FIG. 10 and the corresponding descriptions in the second embodiment).

It should be noted that, in the solid-state imaging device of the present embodiment, it is also preferable to secure 50 [nm] or more as the forming width of the silicide film in the transmission gate 405, from the perspective of preventing the increase of resistance in the transmission gate 405. This is because, as described above, the characteristic of silicide that aggregates when the silicide is formed with the width narrower than a predetermined line width is taken into consideration. This is also to suppress the increase of resistance caused by the line width.

In the present embodiment, it is also possible to adopt a polysilicon film or an amorphous silicon film as a component of the transmission gate 405.

Also, as shown in FIG. 12B, in the image pixel 71 of the variation, part of the transmission gate 705 passes over the photodiode 101, and also passes over the part of the periphery of the rectangular shaped photodiode 101 in the vertical direction and the horizontal direction. Even when such forms are adopted, the area of the transmission gate 705 that corresponds to the periphery of the photodiode 101 is set to include the silicide film, and the remaining area that passes over the photodiode 101 is set to be the silicide unformed area 605a, which does not include the silicide film in the structure. In this way, the solid-state imaging device that includes the image pixel 71 of the present variation can achieve the equivalent advantage to the solid-state imaging device of the above fourth embodiment.

Furthermore, the solid-state imaging device that includes the image pixel 71 of the variation shown in FIG. 12B can also change the structure thereof under appropriate circumstances.

### Fifth Embodiment

The following describes the solid-state imaging device of the fifth embodiment with reference to FIG. 13, which is a schematic view of the structure of the image pixel 51 that is the most distinctive characteristic in the structure of the solid-state imaging device of the present embodiment.

As shown in FIG. 13, the solid-state imaging device of the present embodiment has a multi-pixel cell structure (the present embodiment adopts a two-pixel cell structure as one example), and each image pixel 51 includes (i) a photodiode 501 that is formed on the semiconductor substrate, (ii) a transmission gate 505 that is arranged so as to partially pass over the photodiode 501 in order to transmit the electric charge that is accumulated in the photodiode 501, and (iii) the detection capacity region 502 (floating diffusion region) that stores the electric charge transmitted by the transmission gate 505.

Also, as is the case with the image pixel 11 of the solid-state imaging device 1 of the above described embodiment, the image pixel 51 of the solid-state imaging device of the present embodiment includes a source region 503, a drain region 504, a reset gate 506 and an amplifier gate 507. In addition, in the solid-state imaging device of the present embodiment, a device isolation region that isolates the function regions from each other is formed in each image pixel 51.

The transmission gates 505 are not only extended to connect to the respective photodiodes 501 but also extended to connect to each other as a line so as to remain electrically connected between the adjacent image pixels 51. In the present embodiment, the line is also considered to be the part of the transmission gate 505. Also, the transmission gates 505 may be connected to each other with use of a metallic line arranged in the top layer and a contact plug.

Also, as is the case with the solid-state imaging devices of the above-described embodiments 1-4, the transmission gate 505 that reads out the accumulated electric charge in the photodiode 501 to the floating diffusion region 502 is formed so as to be obliquely diagonal with respect to the photodiode 501 and the floating diffusion region 502, and reads out the electric charge that is accumulated in the photodiode 501 to the floating diffusion region 502 that is located diagonally downward right. In other words, in the solid-state imaging device of the present embodiment, when reading out the electric charge that is accumulated in the photodiode 501 to the floating diffusion region, the transmission gate 505 reads out in the substantially perpendicular direction with respect to the extension direction of the transmission gate 505 (the direction shown by the alternate long and short dash line arrow in FIG. 13).

Also, in the solid-state imaging device of the present embodiment, the shape of the photodiode 501 is set to be substantially symmetric (polygonal shaped or substantially rectangular shaped) in the horizontal direction and the vertical direction (X axial direction and Y axial direction). This is to prevent the distribution of the generated electric charge in the photodiode 501 from varying in the horizontal direction and the vertical direction (X axial direction and Y axial direction), and thereby preventing the deterioration in the shading characteristics of the solid-state imaging device.

Furthermore, in each image pixel 51 of the solid-state imaging device of the present embodiment, (i) the line to connect the transmission gates 505, (ii) the line to connect the reset gates 506, and (iii) the line to connect the amplifier gates 507 are all formed to be nonlinear shaped in order to reduce the proportional area of the depletion region in the image pixel 51, and to increase the proportional area of the photodiode 501 in the image pixel 51.

The solid-state imaging device of the present embodiment that adopts the above-described structure has the following two advantages in addition to the advantages that the solid-state imaging devices of the above-described embodiments 1-4 have.

(3) The third advantage is that, as shown in FIG. 13, the solid-state imaging device of the present embodiment has the transmission gate 505 that is arranged in the oblique direction (Oblique direction with respect to X-Y axial directions) in the area connecting the floating diffusion region (detection capacity region) 502 and the photodiode 501. In the solid-state imaging device of the present embodiment, adopting the above-described structure makes it possible to prevent noise (leakage) caused by a defect and to obtain an excellent images. The following are the explanations about this matter, with reference to FIG. 14A and FIG. 14B. FIG. 14A is a schematic view that shows a structure of the floating diffusion region (detection capacity region) 502 of the solid-state imaging device of the present embodiment. FIG. 14B is a schematic view that shows the floating diffusion region 102 of the solid-state imaging device 1 of the above-described first embodiment.

As shown in FIG. 14B, in the solid-state imaging device of the above-described first embodiment, the margins of the floating diffusion region 102 cross each other substantially perpendicularly in the area 102a. Therefore, the stress in this area may concentrate. This means that, in the case of having the floating diffusion region 102 that has the area 102a whose margins cross each other substantially perpendicularly, a defect may occur in the area 102a, causing noise (leakage).

Meanwhile, as shown in FIG. 14A, the solid-state imaging device of the present embodiment has the floating diffusion region 502 whose margins cross obtusely in the area 502a. Therefore, the stress rarely concentrates in the area 502a. This means that, the solid-state imaging device of the present embodiment can suppress noise (leakage current) even lower than the solid-state imaging device 1 of the above-described first embodiment.

(4) As to the fourth advantage, the solid-state imaging device of the present embodiment adopts the multi-pixel cell and the oblique arrangement of the transmission gate 505, which makes it possible to obtain the gate length greater than the solid-state imaging device that adopts the one-pixel cell structure. This is because, in the solid-state imaging device 1 of the above-described first embodiment that adopts one-pixel cell, as shown in FIG. 3, the gate length of the transmission gate 105 is determined by the positional relationship between the reset gate 106 and the transmission gate 105, depending on a minimum processing measure.

On the other hand, in the solid-state imaging device of the present embodiment that adopts the multi-pixel cell structure, as shown in FIG. 13, it is possible to obtain a large gate length of the transmission gate 505 by symmetrically arranging the transmission gates 505 in the upper and lower image pixels 51. In other words, the solid-state imaging device of the present embodiment can transmit the electric charge from the photodiode 501 to the transmission gate 505 easily and satisfactorily.

It should be noted that the present embodiment can also adopt the polysilicon film and the amorphous silicon film as a component of the transmission gate 505.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be constructed as being included therein.

1-13. (canceled)

14. A solid-state imaging device including a plurality of image pixels that are arranged along a main surface of a semiconductor substrate, the solid-state imaging device comprising:
a photodiode that is included in each of the plurality of image pixels, and converts incident light into an electric charge; and
a transmission gate that includes a first region having a laminated body of a silicon film and a silicide film, and a second region having a silicon film, not a silicide film, both being arranged along the main surface of the semiconductor substrate, wherein all of the second region and at least a part of the first region are disposed over part of the photodiode when viewed from a thickness direction of the semiconductor substrate.

15. The solid-state imaging device of claim 14, wherein in the thickness direction of the semiconductor substrate, an upper main surface of the silicon film in the second region is positioned closer to the semiconductor substrate than an upper main surface of the silicide film of the first region.

17. The solid-state imaging device of claim 14, wherein above the photodiode, the second region is arranged closer to a center of the photodiode than the first region, in a direction along the main surface of the semiconductor substrate.

18. The solid-state imaging device of claim 14, wherein the photodiode is substantially rectangular shaped in the thickness direction of the semiconductor substrate.

19. The solid-state imaging device of the claim 14, wherein electric charge from the photodiode is readout in an orthogonal direction with respect to the oblique direction.

20. The solid-state imaging device of the claim 14, wherein the silicide film includes at least one material selected from cobalt silicide, nickel silicide and titanium silicide.

21. The solid-state imaging device of claim 14, wherein
the plurality of image pixels each include an n-type transistor, and
the first region is arranged so as to cover at least part of areas among a drain region, a source region and a gate of the n-type transistor.

22. The solid-state imaging device of claim 14, wherein
each of the plurality of image pixels has a detection capacity region that reads out the electric charge generated by a photoelectric conversion in the photodiode, and
the first region covers over an area that includes at least a contact region of the detection capacity region.

23. The solid-state imaging device of claim 14, including a multi-pixel cell structure.

24. The solid-state imaging device of claim 14, wherein
the photodiode is polygonal shaped in the thickness direction of the semiconductor substrate, and
the transmission gate passes over at least one of peripheral sides of the photodiode in an oblique direction.
